(19) United States
(12) Patent Application Publication
(10) Pub. No.: US 2024/0339924 A1
(43) Pub. Date: Oct. 10, 2024

(54) DRIVING APPARATUS FOR SWITCH

(71) Applicant: DENSO CORPORATION, Kariya-city (JP)

(72) Inventor: Akira TOKUMASU, Kariya-city (JP)

(73) Assignee: DENSO CORPORATION, Kariya-city (JP)

(21) Appl. No.: 18/750,139

(22) Filed: Jun. 21, 2024

Related U.S. Application Data
(63) Continuation of application No. PCT/JP2022/043257, filed on Nov. 23, 2022.

(30) Foreign Application Priority Data
Dec. 21, 2021 (JP) 2021-207491

(51) Int. Cl. H02M 1/088; H02M 1/00; H02M 1/32; H02M 1/38; H02M 7/5387

(52) U.S. Cl. CPC H02M 1/088; H02M 1/0054; H02M 1/32; H02M 1/38; H02M 7/53871

(57) ABSTRACT

A driving apparatus of a switch drives upper and lower arm switches mutually connected in serial. The driving apparatus of the switch is provided with a discharge unit that discharges electric charges from an OFF side switch, a determination unit that determines whether the OFF side switch is ON or OFF, a fast-discharge unit that changes a discharge rate of discharging electric charges, to be higher than a discharge rate in a period from when electric charges in the OFF side switch start to discharge to when determined that the OFF side switch is turned OFF, and a charge unit that charges an ON side switch.

### CROSS-REFERENCE OF RELATED APPLICATIONS

This application is the U.S. bypass application of International Application No. PCT/JP2022/043257 filed on Nov. 23, 2022, which designated the U.S. and claims priority to Japanese Patent Application No. 2021-207491 filed on Dec. 21, 2021, the contents of which is incorporated herein by reference.

### BACKGROUND

### Technical Field

The present disclosure relates to a driving apparatus for switch.

### Description of the Related Art

Conventionally, a switch driving apparatus that drives upper and lower arm switches mutually connected in series is known.

A driving apparatus is configured to turn the ON-side switch in an arm opposite to an arm of the OFF side switch to be ON with a dead time as a period where both of the upper and lower arm switches are being OFF, when determined that the OFF side switch in the upper and lower arm switches is turned OFF.

### SUMMARY

According to the present disclosure, a switch driving apparatus that drives upper and lower arm switches mutually connected in series is provided. The switch driving apparatus includes: a discharge unit that causes electric charges to be discharged from a gate of an OFF side switch as an one switch in the upper and lower arm switches, thereby turning the OFF side switch to be OFF; a determination unit that determines whether the OFF side switch is ON or OFF; a fast-discharge unit that changes, when the determination unit determines that the OFF side switch is turned OFF, a discharge rate of discharging in which electric charges in the gate of the OFF side switch is discharged, to be higher than a discharge rate in a period from when electric charges in the gate of the OFF side switch start to discharge to when determined that the OFF side switch is turned OFF; and a charge unit that charges, when the determination unit determines that the OFF side switch is turned OFF, a gate of an ON side switch in an arm opposite to an arm of the OFF side switch in the upper and lower arm switches with electric charges, thereby turning the ON side switch to be ON.

### BRIEF DESCRIPTION OF THE DRAWINGS

The above-described objects and other objects, features and advantages of the present disclosure will be clarified further by the following detailed description with reference to the accompanying drawings. The drawings are:

FIG. 1 is a diagram showing an overall configuration of a control system according to a first embodiment;

FIG. 2 is a diagram showing a configuration of a control apparatus;

FIG. 3 is a timing diagram showing a control in a comparative example;

FIG. 4 is a timing diagram showing a control in a comparative example;

FIG. 5 is a timing diagram showing an example of a control executed by the control apparatus; and

FIG. 6 is a diagram showing a configuration of a control apparatus according to a second embodiment.

### DETAILED DESCRIPTION OF THE PREFERRED EMBODIMENTS

Conventionally, for example, as disclosed in JP-A-2020-96444, a switch driving apparatus that drives upper and lower arm switches mutually connected in series is known.

A driving apparatus is configured to turn the ON-side switch in an arm opposite to an arm of the OFF side switch to be ON with a dead time as a period where both of the upper and lower arm switches are being OFF, when determined that the OFF side switch in the upper and lower arm switches is turned OFF. The dead time is determined in order to prevent a short-circuit between an upper arm unit and a lower arm unit where both arm switches are turned ON.

For example, a dead time may preferably be shortened in order to reduce a switching loss occurring due to a state-change of switches. However, when excessively reducing the dead time, a short-circuit between an upper arm unit and a lower arm unit may occur.

### First Embodiment

Hereinafter, with reference to drawings, a first embodiment in which a driving apparatus according to a present disclosure is embodied will be described. The driving apparatus according to the present embodiment is applied to a three-phase inverter as a power converter. According to the present embodiment, the control system provided with an inverter is mounted on an electric vehicle, a hybrid vehicle or the like.

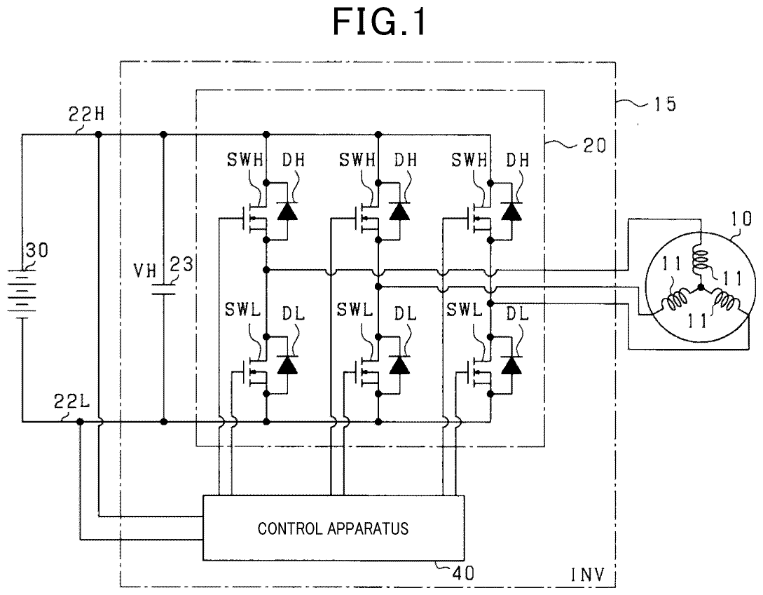

As shown in FIG. 1, the control system is provided with a rotary electric machine 10 and an inverter 15. The rotary electric machine serves as an on-vehicle main machine where the rotor thereof is capable of transmitting a motive force with a unshown driving wheels. According to the present embodiment, a synchronous machine is utilized as the rotary electric machine. Specifically, a permanent magnet synchronous machine is utilized.

The inverter 15 is provided with a switching device unit 20. The switching device 20 is provided with series-connected bodies each composed of an upper arm switch

SWH and a lower arm switch SWL for three-phase configuration. In each phase, a first end of a wiring 11 of the rotary electric machine 10 is connected to a connection point between the upper arm switch SWH and the lower arm switch SWL. The second ends of respective wirings 11 are connected together at the neutral point. The respective wirings 11 are arranged to be mutually shifted by 120° of an electrical angle. According to the present embodiment, each of the switches SWH and SWL is configured of a voltage-controlled type semiconductor switching element, more specifically, a N-channel MOSFET is utilized. The upper and lower arm switches SWH and SWL include upper and lower arm diodes DH and DL as body diodes.

A positive terminal of a DC power source 30 is connected to drain terminals as high potential side terminals of respective upper arm switches SWH via a high potential side electrical path 22H. A negative terminal of the DC power source 30 is connected to source terminals as low potential side terminals of respective lower arm switches SWL via the low potential side electrical path 22L. According to the present embodiment, the DC power source 30 is a secondary battery of which the output voltage (rated voltage) is, for example, higher than 100V.

The inverter 15 is provided with a capacitor 23. The capacitor 23 electrically connects the high potential side electrical path 22H and the low potential side electrical path 22L. Note that the capacitor 23 may be provided outside the inverter 15.

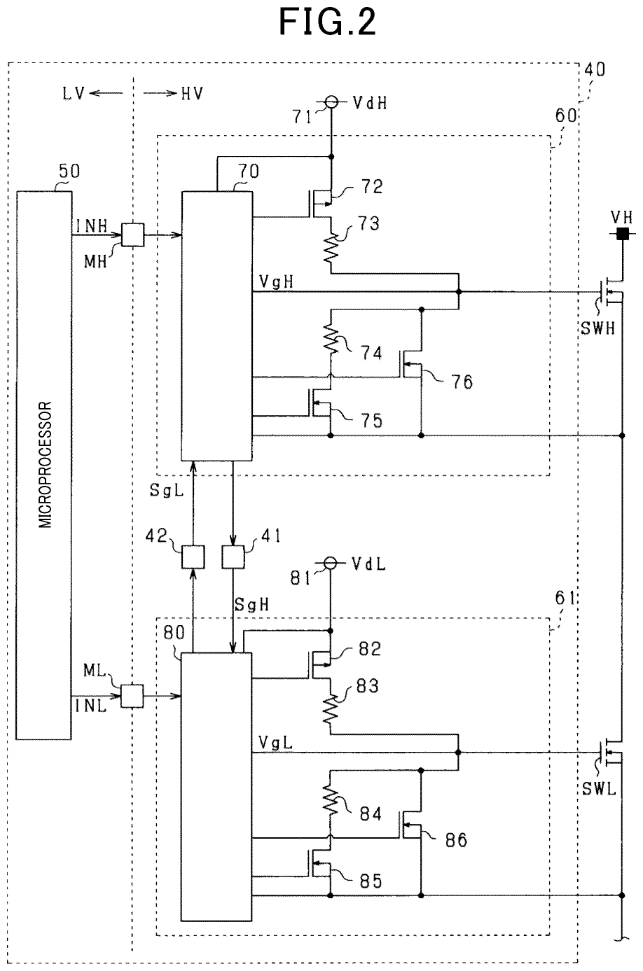

The inverter 15 is provided with a control apparatus 40. In the followings, with reference to FIG. 2, a configuration of the control apparatus 40 will be described.

The control apparatus 40 is provided with a microprocessor 50, upper and lower arm drivers 60 and 61, and upper and lower arm insulation elements MH and ML. The control apparatus 40 includes a high voltage region HV connected to the inverter 15 and a low voltage region LV electrically isolated from the high voltage region HV. The microprocessor 50 is provided in the low voltage region LV, the upper and low arm drivers 60 and 61 are provided in the high voltage region HV, and the upper and lower arm insulation elements MH and ML are provided between the high voltage region HV and the low voltage region LV.

The microprocessor 50 is provided with CPU. The microprocessor 50 serves as a command generation unit that generates upper and lower arm switching commands INH and INL corresponding to the upper and lower arm drivers 60 and 61 so as to control a controlled variable of the rotary electric machine 10 to be corresponding command value. The controlled variable is, for example, a torque. Note that the microprocessor 50 generates the upper and lower arm switching commends INH and INL such that the upper arm switch SWH and the lower arm switch SWL are alternately turned ON in each phase. In the present embodiment, for respective commands INH and INL, logical high indicates an ON command and logical low indicates an OFF command.

The upper arm insulation element MH insulates between the microprocessor 50 and the upper arm driver 60 and transmits the upper arm switching command INH to the upper arm driver 60. The lower arm insulation element ML insulates the microprocessor 50 and the lower arm driver 61 and transmits the lower arm switching command INL to the lower arm driver 61. According to the present embodiment, respective insulation elements MH and ML are configured of magnetic couplers or photocouplers.

The upper arm driver 60 is provided with an upper arm driving unit 70. An upper arm switching command INH generated by the microprocessor 50 is transmitted to the upper arm driving unit 70.

The upper arm driver 60 is provided with an upper arm constant voltage source 71, an upper arm charge switch 72 and an upper arm charge resistor 73. According to the present embodiment, the upper arm charge switch 72 is configured of a P-channel MOSFET. The source terminal of the upper arm charge switch 72 is connected to the upper arm constant voltage source 71. The drain terminal of the upper arm charge switch 72 is connected to the first end of the upper arm charge resistor 73. The second end of the upper arm charge resistor 73 is connected to the gate terminal of the upper arm switch SWH. The upper arm drive voltage VdH outputted from the upper arm constant voltage source 71 serves as a power source voltage supplied to the gate terminal of the upper arm switch SWH. According to the present embodiment, the upper arm driving unit 70, the upper arm charge switch 72 and the upper arm charge resistor 73 correspond to upper arm charge unit.

The upper arm driver 60 is provided with an upper arm discharge resistor 74 and an upper arm discharge switch 75. According to the present embodiment, the upper arm discharge switch 75 is configured of N-channel MOSFET. The first end of the upper arm discharge resistor 74 is connected to the gate terminal of the upper arm switch SWH, and the second end of the upper arm discharge resistor 74 is connected to the drain terminal of the upper arm discharge switch 75. The source terminal of the upper arm discharge switch 75 is connected to the source terminal of the upper arm switch SWH. According to the present embodiment, the upper arm driving unit 70, the upper arm discharge resistor 74 and the upper arm discharge switch 75 correspond to upper arm discharge unit.

The lower arm driver 61 is provided with a lower arm driving unit 80. A lower arm switching command INL is transmitted to the lower arm driving unit 80.

The lower arm driver 61 is provided with a lower arm constant voltage source 81, a lower arm charge switch 82 and a lower arm charge resistor 83. According to the present embodiment, the lower arm charge switch 82 is configured of a P-channel MOSFET. The source terminal of the lower arm charge switch 82 is connected to the lower arm constant voltage source 81. The drain terminal of the lower arm charge switch 82 is connected to the first end of the lower arm charge resistor 83. The second end of the lower arm charge resistor 83 is connected to the gate terminal of the lower arm switch SWL. The second end of the lower arm charge resistor 83 is connected to the gate terminal of the lower arm switch SWL. The lower arm drive voltage VdL outputted from the lower arm constant voltage source 81 serves as a power source voltage supplied to the gate terminal of the lower arm switch SWL. According to the present embodiment, the lower arm driving unit 80, the lower arm charge switch 82 and the lower arm charge resistor 83 correspond to lower arm charge unit.

The lower arm driver 61 is provided with a lower arm discharge resistor 84 and a lower arm discharge switch 85. According to the present embodiment, the lower arm discharge switch 85 is configured of a N-channel MOSFET. The first end of the lower arm discharge resistor 84 is connected to the gate terminal of the lower arm switch SWL, and the second end of the lower arm discharge switch 84 is connected to the drain terminal of the lower arm discharge switch 85. The source terminal of the lower arm discharge switch 85 is connected to the source terminal of the lower arm switch SWL. According to the present embodiment, the lower arm driving unit 80, the lower arm discharge resistor 84 and the lower arm discharge switch 85 correspond to lower arm discharge unit.

The control apparatus 50 alternately turns the respective switches SWH and SWL to be ON with a dead time as a period where both of the switches SWH and SWL are being OFF. The dead time DT refers to a period where both of the switches SWH and SWL are being OFF. The dead time DT is provided in order to suppress occurrence of short-circuit between upper arm unit and lower arm unit where both of the switches SWH and SWL are being ON.

During the dead time DT, a reflux current flows through a closed loop circuit including an upper arm diode DH in one phase and a lower arm diode DL in the other phase. A power loss caused by a current flowing through the respective diodes DH and DL is larger than a power loss caused by a current flowing through the respective switches SWH and SWL being in an ON state. Hence, the dead time DT may preferably be shortened so as to reduce the power loss caused by switching the respective switches SWH and SWL. Further, in view of improving a voltage utilization ratio of the inverter 15, the dead time DT may preferably be shortened.

In order to shortened the dead time DT, a dead time target value DT* set by the microprocessor 50 may be set to be shorter. The dead time target value DT* refers to a period where state of the respective switching commands INH and INL are both logical L. However, in view of suppressing occurrence of short-circuit between upper and lower arm units, some margin is required for setting the dead time margin value DT*. Specifically, the turn-off period from when L level of respective switching commands INH and INL are outputted to when the respective switches SWH and SWL turn OFF, varies depending on current flowing through the respective switches SWH and SWL, temperature of the respective switches SWH and SWL and manufacturing variation of the respective switches SWH and SWL. Hence, in order to suppress occurrence of short-circuit between upper and lower arm units, taking a variation of the turn-off period caused by the above-described reason into consideration, a margin is required to be set for the dead time target value DT*. When setting the dead time target value DT* to have a larger margin, probability of occurrence of short-circuit between the upper and lower arm units becomes smaller, but the dead time DT may be excessively longer.

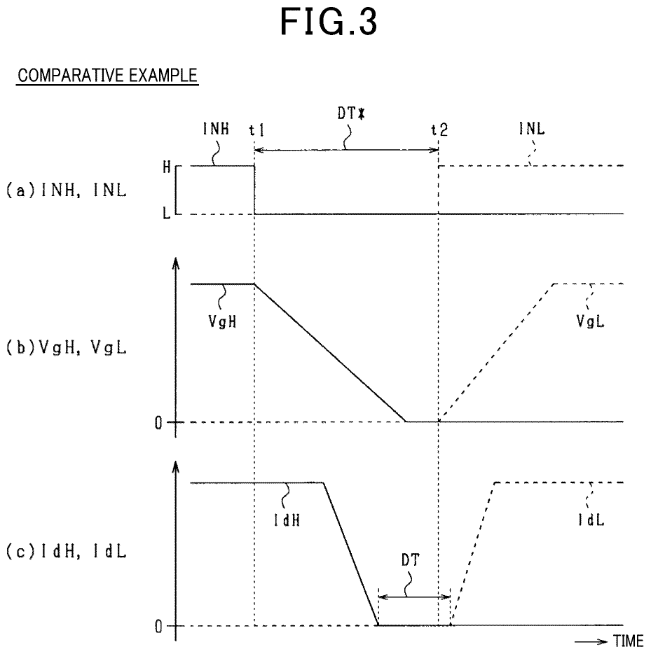

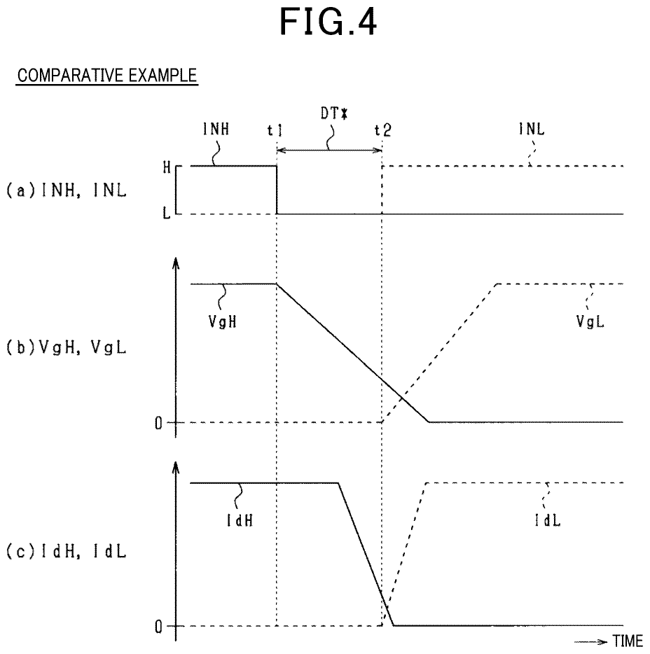

FIGS. 3 and 4 shows a control according to a comparative example. FIG. 3 is a comparative example in the case where the dead time target value DT* is set to be excessively longer. FIG. 4 is a comparative example in the case where the dead time target value DT* is set to be excessively shorter. In FIGS. 3 and 4, a timing (a) indicates a logical state of respective switching commands INH and INL, a timing (b) indicates a change in the gate voltages VgH and VgL of the respective switches SWH and SWL, and a timing (c) indicates a change in the drain current IdH and IdL flowing through the respective switches SWH and SWL.

At time t1, the logical state of the upper arm switching command INH is changed to be L. Thus, the upper arm driving unit 70 drives the upper arm charge switch 72 to be OFF and drives the upper arm discharge switch 75 to be ON, thereby causing electric charges to be discharged from the gate of the upper arm switch SWH. Hence, the gate voltage VgH of the upper arm switch SWH starts to decrease.

At time t2, the logical state of the lower arm switching command INL is changed to be H. Thus, the lower arm driving unit 80 turns the lower arm charge switch 82 to be ON and the lower arm discharge switch 85 to be OFF, thereby causing the gate of the lower arm discharge switch 85 to be charged with electric charges. Thus, the gate voltage VgL and the drain current IdL of the lower arm switch SWL increase and the lower arm switch SWL turns ON.

According to a comparative example shown in FIG. 3, the dead time target value DT* is set to be excessively longer, whereby occurrence of a short-circuit between upper and lower arm units is suppressed while causing the dead time DT to be longer. As a result, a power loss due to the switching may be increased. According to the comparative example shown in FIG. 4, the dead time target value DT* is set to be shorter, and the dead time DT is shortened. However, a short-circuit between upper and lower arm units may occur, causing a decline of reliability.

In this respect, the control apparatus 40 has the following configuration in order to shorten the dead time while suppressing occurrence of a short-circuit between the upper arm unit and the lower arm unit.

Referring back to the explanation of FIG. 2, the upper arm driving unit 70 determines whether the upper arm switch SWH is in an ON state or an OFF state. According to the present embodiment, the upper arm driving unit 70 inputs the gate voltage VgH of the upper arm switch SWH. The upper arm driving unit 70 determines whether the gate voltage VgH of the upper arm switch SWH is less than a determination voltage of the upper arm switch SWH. According to the present embodiment, the determination voltage of the upper arm switch SWH is set to be a threshold voltage Vth of the upper arm switch SWH. The threshold voltage Vth of the upper arm switch SWH refers to the gate voltage VgH that allows the switching state to change from one state to the other state between an ON state and OFF state.

Specifically, the upper arm driving unit 70 determines that the upper arm switch SWH turns ON when determined that gate voltage VgH of the upper arm switch SWH is higher than or equal to the determination voltage of the upper arm switch SWH, and outputs an upper arm transmission signal SgH of which the state is logic L. On the other hand, the upper arm driving unit 70 determines that the upper arm switch SWH turns OFF when determined that gate voltage VgH of the upper arm switch SWH is less than the determination voltage of the upper arm switch SWH, and outputs an upper arm transmission signal SgH of which the state is logic H. The lower arm driving unit 80 inputs the upper arm transmission signal SgH via a first transmission unit 41 disposed in the high voltage region HV of the control apparatus 40. According to the present embodiment, the first transmission unit 41 is configured of a magnetic coupler or a photocoupler.

The lower arm driving unit 80 determines whether the upper arm switch SWH is in an ON state or an OFF state. According to the present embodiment, the lower arm driving unit 80 inputs a gate voltage VgL of the lower arm switch SWL. The lower arm driving unit 80 determines whether the gate voltage VgL of the lower arm switch SWL is less than a determination voltage of the lower arm switch SWL. According to the present embodiment, the determination voltage of the lower arm switch SWL is set to be the threshold voltage Vth of the lower arm switch SWL. The threshold voltage Vth of the lower arm switch SWL refers to a gate voltage VgL that allows the switching state to change from one state to the other state between an ON state and OFF state.

Specifically, the lower arm driving unit 80 determines that the lower arm switch SWL is ON when determined that the gate voltage VgL of the lower arm switch SWL is higher than or equal to the determination voltage of the lower arm switch SWL, and outputs the lower arm transmission signal SgL of which the state is logic L. On the other hand, the lower arm driving unit 80 determines that the lower arm switch SWL is OFF when determined that the gate voltage VgL of the lower arm switch SWL is less than the determination voltage of the lower arm switch SWL, and outputs the lower arm transmission signal SgL of which the state is logic H. The upper arm driving unit 70 inputs the lower arm transmission signal SgL via a second transmission unit 42 disposed in the high voltage region HV of the control apparatus 40. According to the present embodiment, the second transmission unit 42 is configured of a magnetic coupler or a photocoupler. According to the present embodiment, the upper and lower arm driving units 70 and 80 correspond to acquiring unit and determination unit.

The respective drivers 60 and 61 are provided with fast-discharge units. The fast-discharge unit changes, when determined that the OFF side switch is turned OFF, a discharge rate of discharging in which electric charges in the gate of the OFF side switch is discharged, to be higher than a discharge rate in a period from when electric charges in the gate of the OFF side switch starts to discharge to when determined that the OFF side switch is turned OFF. Here, the OFF side switch serves as a switch between respective switches SWH and SWL in an arm where a logic L switching command is generated, and the ON side switch serves as a switch between respective switches SWH and SWL in an arm where a logic H switching command is generated. According to the present embodiment, as the fast-discharge unit, the upper arm driver 60 is provided with an upper arm OFF-hold switch 76 and the lower arm driver 61 is provided with a lower arm OFF-hold switch 86.

The upper arm OFF-hold switch 76 is configured of a N-channel MOSFET. The drain terminal of the upper arm OFF-hold switch 76 is connected to the gate terminal of the upper arm switch SWH, and the source terminal of the upper arm OFF-hold switch 76 is connected to the source terminal of the upper arm switch SWH. The gate terminal of the upper arm OFF-hold switch 76 is connected to the upper arm driving unit 70.

The upper arm OFF-hold switch 76 is turned ON responding to the upper arm transmission signal SgH of which the state is logic H and turned OFF responding to the lower arm transmission signal SgH of which the state is logic L. Specifically, the upper arm OFF-hold switch 76 is turned ON when determined that the upper arm switch SWH is turned OFF, and the upper arm OFF-hold switch 76 is turned OFF when determined that the upper arm switch SWH is turned ON. The upper arm OFF-hold switch 76 is turned ON, whereby the gate and the source of the upper arm switch SWH are short-circuited. Thus, the discharge rate when discharging the gate charges of the upper arm switch SWH via the upper arm OFF-hold switch 76 becomes higher than the discharge rate when discharging the gate charges of the upper arm switch SWH via an upper arm discharge switch 75.

The lower arm OFF-hold switch 86 is configured of N-channel MOSFET. The drain terminal of the lower arm OFF-hold switch 86 is connected to the gate terminal of the lower arm switch SWL, and the source terminal of the lower arm OFF-hold switch 86 is connected to the source terminal of the lower arm switch SWL. The gate terminal of the lower arm OFF-hold switch 86 is connected to the lower arm driving unit 80.

The lower arm OFF-hold switch 86 is turned ON by the lower arm transmission signal SgL of which the state is logic H and turned OFF by the lower arm transmission signal SgL of which the state is logic L. That is, the lower arm OFF-hold switch 86 is turned ON when determined that the lower arm switch SWL is turned OFF, and the lower arm OFF-hold switch 86 is turned OFF when determined that the lower arm switch SWL is turned ON. The lower arm OFF-hold switch is turned ON, whereby the gate and the source of the lower arm switch SWL are short-circuited. Thus, the discharge rate for discharging the gate charges of the lower arm switch SWL via the lower arm OFF-hold switch 86 is higher than the discharge rate for discharging the gate charges of the lower arm switch SWL via the lower arm OFF-hold switch 85.

The respective OFF-hold switches 76 and 86 as the fast-discharge unit also serve as switches for suppressing occurrence of a self-turn ON. Specifically, for the self-turn ON, due to a tuning ON of the ON side switch, electric charges are supplied to the gate of the OFF side switch via a parasitic capacitance in the OFF side switch, for example, whereby the gate voltage of the OFF side switch may be higher than the threshold voltage Vth. In this case, a self-turn ON possibly occurs as a phenomenon in which the OFF side switch is erroneously turned ON despite the OFF-state of the OFF side switch being required to be maintained. When the respective OFF-hold switches 76 and 86 are turned ON, the gate and the source of the OFF side switch are short-circuited. Thus, the self-turn ON is avoided.

The upper arm driving unit 70 turns the upper arm charge switch 72 to be ON, and turns the upper arm discharge switch 75 and the upper arm OFF-hold switch 76 to be OFF in the case where the logic state of the upper arm switching command INH is H and the logic state of the lower arm transmission signal SgL is H. Thus, the gate of the upper arm switch SWH is charged with electric charges. As a result, the gate voltage VgH of the upper arm switch SWH becomes higher than the threshold voltage Vth and the upper arm switch SWH is turned ON.

The upper arm driving unit 70 turns the upper arm charge switch 72 and the upper arm OFF-hold switch 76 to be OFF and turns the upper arm discharge switch 75 to be ON in the case where at least one of the upper arm switching command INH and the lower arm transmission signal SgL is logic L. Thus, electric charges start to be discharged from the gate of the upper arm switch SWH.

The upper arm driving unit 70 changes the logic state of the upper arm transmission signal SgH to be H when determined that the gate voltage VgH of the upper arm switch SWH is less than the determination voltage of the upper arm switch SWH. Since the logic state of the upper arm transmission signal SgH is H, the upper arm OFF-hold switch is turned ON.

The lower arm driving unit 80 turns the lower arm charge switch 82 to be ON and turns the lower arm discharge switch 85 and the lower arm OFF-hold switch 86 to be ON in the case where the logic state of the lower arm switching command INL is H and the logic state of the upper arm transmission signal SgH is H. Thus, the gate of the lower arm switch SWL is charged with electric charges. As a result, the gate voltage VgL of the lower arm switch SWL becomes higher than the determination voltage, and the lower arm switch SWL is turned ON.

The lower arm driving unit 80 turns the lower arm charge switch 82 and the lower arm OFF-hold switch 86 to be OFF and turns the lower arm discharge switch 85 to be ON in the case where at least one of the lower arm switching command INL and the lower arm transmission signal SgH is logic L. Thus, electric charges at the gate of the lower arm switch SWL start to be discharged.

The lower arm driving unit 80 changes the logic state of the lower arm transmission signal SgL to be H when determined that the gate voltage of the lower arm switch SWL is less than the determination voltage of the lower arm switch SWL. With this change, since the logic state of the lower arm transmission signal SgL is H, the lower arm OFF-hold switch is turned ON.

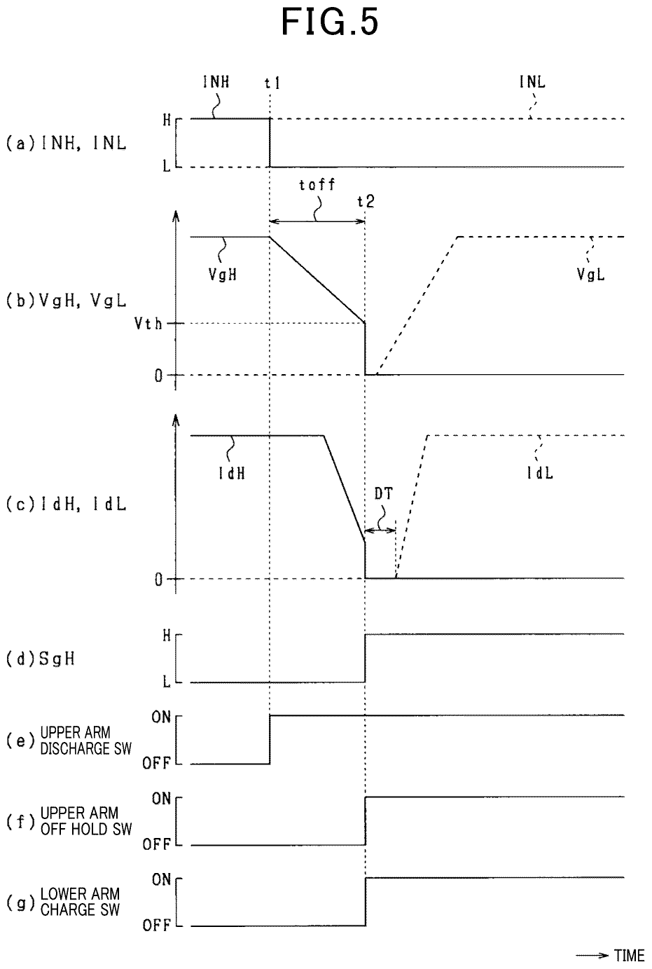

FIG. 5 shows an example of a control of the control apparatus 40. In FIG. 5, timings (a) to (c) correspond to the timings (a) to (c) shown in FIGS. 3 and 4, the timing (d) shows a logical state of the upper arm transmission signal SgH, the timing (e) shows a state of change between ON and OFF of the lower arm discharge switch 75, a timing (f) shows a state of change between ON and OFF of the upper arm OFF-hold switch 76 and a timing (g) shows a state of change between ON and OFF of the lower arm charge switch 82. Note that FIG. 5 exemplifies a control in the case where the upper arm switch SWH serves as an OFF side switch and the lower arm switch SWL serves as an ON side switch.

At time t1, the logic state of the upper arm switching command INH is L and the logic state of the lower arm switching command INL is H. That is, according to the present embodiment, the dead time target value DT* is set to be 0. Thus, the dead time target value DT* is shorter than the turn-off period toff. The turn-off period toff refers to a period from when the logic state of the switching command of the OFF side switch is changed to be L to when the gate voltage of the OFF side switch becomes lower than the threshold voltage. The logic state of the upper arm switching command INH is caused to be L, whereby the upper arm discharge switch 75 is turned ON. Thus, the gate voltage VgH of the upper arm switch SWH starts to decrease. Note that since the logic state of the upper arm transmission signal SgH is L, the upper arm OFF-hold switch 76 and the lower arm charge switch 82 is caused to be OFF.

At time t2, the gate voltage VgH of the upper arm switch SWH is below the determination voltage. Thus, the logic state of the upper arm transmission signal SgH is changed to be H. Since the logic state of the upper arm transmission signal SgH is H, the upper arm OFF-hold switch 76 is turned ON. Hence, the gate and the source of the upper arm switch SWH are short-circuited. In this case, the discharge rate of the gate charges of the upper arm switch SWH is higher than the discharge rate of the gate charges of the upper arm switch SWH in the turn-off period toff. As a result, the gate voltage VgH and the drain current IdH of the upper arm switch SWH rapidly decrease.

Also, at time t2, since the logic state of the lower arm switching command INL is H and the logic state of the upper arm transmission signal SgH is H, the lower arm charge switch 82 is turned ON. Thus, the gate voltage VgL of the lower arm switch SWL starts to increase.

In this case, the gate voltage VgH of the upper arm switch SWH rapidly decreases and the gate voltage VgL of the lower arm switch SWL starts to increase. Thus, the drain current IdH of the upper arm switch SWH is caused to be 0 and then the drain current IdH of the lower arm switch SWL promptly starts to flow. Hence, the dead time DT can be shortened while suppressing occurrence of a short-circuit between the upper and lower arms.

According to the above-described embodiment, the following effects and advantages can be obtained.

When determined that the OFF side switch is turned OFF, the gate and the source of the OFF side switch are short-circuited. In this case, the discharge rate of gate charges of the OFF side switch is higher than the discharge rate of gate charges of the OFF side switch during the turn-off period toff. Thus, the gate voltage of the OFF side switch rapidly decreases. As a result, after determining that the OFF side switch is turned OFF, the drain current flowing through the OFF side switch is promptly cutoff.

Further, when determined that the OFF side switch is turned OFF, the gate of the ON side switch is charged with electric charges. In other words, since the ON side switch is turned ON after determining that the OFF side switch in an opposite arm is turned OFF, a short-circuit between the upper and lower units can be avoided.

Since the drain current of the OFF side switch is cutoff and the gate of the ON side switch is charged with electric charges in response to a determination that the OFF side switch is turned OFF as a trigger, the dead time DT can be shortened while suppressing occurrence of a short-circuit between upper and lower arm units.

The gate voltage of the OFF side switch is below the threshold voltage, whereby the switching state of the OFF side switch changes from the ON state to the OFF state. In this respect, according to the present embodiment, the determination voltage used for determining whether the OFF side switch is turned OFF, is set to be the threshold voltage of the OFF side switch. Thus, the OFF side switch can be accurately determined that it is turned OFF.

When determined that the OFF side switch is turned OFF, an OFF-hold switch is turned ON which is in an arm where the OFF side switch is turned OFF. Thus, occurrence of self-turn ON is suppressed, whereby occurrence of short-circuit between upper and lower arm units can be reliably avoided.

With the respective transmission units 41 and 42 disposed in the high voltage region HV, the respective transmission signals Sg1 and Sg2 are transmitted between the respective driving units 70 and 80 disposed in the high voltage region HV. Thus, compared to a case where the microprocessor 50 disposed in the low voltage region LV determines whether respective switch SWH and SWL turn ON or OFF, transmission delay of the respective transmission signals Sg1 and Sg2 can be reduced.

The dead time target value DT* is set to be shorter than the turn-off period toff. Thus, the logical state of the switching command of the ON side switch is set to be H in advance before determining that the OFF side switch is turned OFF. Hence, it is determined that the OFF side switch is turned OFF, whereby the gate of the ON switch can promptly start to be charged with electric charge. As a result, the dead time DT can be accurately shortened.

As an OFF determination condition of the OFF side switch, a condition is utilized in which the gate voltage of the OFF side switch is below the threshold voltage. Thus, even when the turn-off period toff varies due to a current flowing through respective switches SWH and SWL, a temperature of the respective switches SWH and SWL, a production tolerance of the respective switches SWH and SWL or the like, the determination whether the OFF side is turned off can be accurately performed. Therefore, although the turn-OFF period toff of the OFF side switch changes, with an OFF determination of the OFF side switch as a trigger, a cutoff of the drain current in the OFF side switch and a gate charge of the ON side switch can be accurately performed.

Even after the logic state of the upper arm transmission signal SgH is changed to be H, the ON state of the upper arm switch 75 is continued. Thus, a period is produced where both of the upper arm discharge switch 75 and the upper arm OFF-hold switch 76 are ON. Hence, discharging of the gate charges of the upper arm switch SWH can be prevented from being stopped because of a period being temporarily produced where both of the upper arm discharge switch 75 and the upper arm OFF-hold switch 76 are OFF. Even after the logic state of the lower arm transmission signal SgL is changed to be H, the ON state of the lower arm switch 85 is continued. Thus, a period is produced where both of the lower arm discharge switch 85 and the lower arm OFF-hold switch 86 are ON. Hence, discharging of the gate charges of the lower arm switch SWL can be prevented from being stopped because of a period being temporarily produced where both of the lower arm discharge switch 85 and the lower arm OFF-hold switch 86 are OFF.

### Second Embodiment

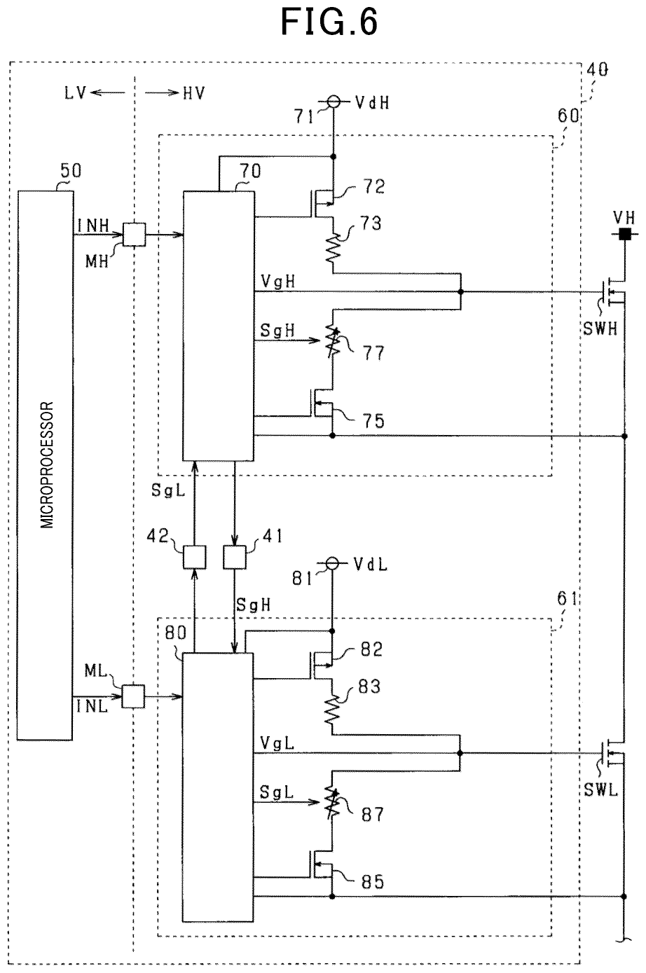

Hereinafter, with reference to the drawings, configurations different from those in the first embodiment will mainly be described. According to the present embodiment, a configuration of the fast-discharge unit is changed. FIG. 6 shows a configuration of the control apparatus 40. In FIG. 6, the same reference symbols are applied to configurations the same as those shown in FIG. 2 for the sake of convenience.

The upper arm driver 60 is provided with an upper arm variable resistor 77 instead of the upper arm discharge resistor 74. The first end of the upper arm variable resistor 77 is connected to the gate of the upper arm switch SWH, and the second end of the upper arm variable resistor 77 is connected to the drain of the upper arm discharge switch 75. When logic H of the upper arm transmission signal SgH is inputted, the resistance value of the upper arm variable resistor 77 is set to be smaller than that of a case where logic L of the upper arm transmission signal SgH is inputted. The upper arm variable resistor 77 includes, for example, a plurality of resistors having different resistances in which a resistor connected between the gate of the upper arm switch SWH and the drain of the upper arm discharge switch 75 is changed among the plurality of resistors, thereby changing the resistance value. When setting the resistance value of the upper arm resistor 77 to be smaller, the discharge rate of the gate charges in the upper arm switch SWH is caused to be higher.

The lower arm driver 61 is provided with a lower arm variable resistor 87 instead of the lower arm discharge resistor 84. The first end of the lower arm variable resistor 87 is connected to the gate of the lower arm switch SWL, and the second end of the lower arm variable resistor 87 is connected to the drain of the lower arm discharge switch 85. When logic H of the lower arm transmission signal SgL is inputted, the resistance value of the lower arm variable resistor 87 is set to be smaller than that of a case where logic L of the lower arm transmission signal SgH is inputted. The lower arm variable resistor 87 includes, for example, a plurality of resistors having different resistances in which a resistor connected between the gate of the lower arm switch SWL and the drain of the lower arm discharge switch 85 is changed among the plurality of resistors, thereby changing the resistance value. When setting the resistance value of the lower arm resistor 87 to be smaller, the discharge rate of the gate charges in the lower arm switch SWL is caused to be higher.

### Other Embodiments

Note that the above-described respective embodiments may be modified in the following manners.

The determination voltage of the upper arm switch SWH is not limited to the threshold voltage Vth of the upper arm switch SWH. The determination voltage of the upper arm switch SWH may be set to be higher than the threshold Vth of the upper arm switch SWH taking a signal delay in the control apparatus 40 into consideration. Also, the determination voltage of the upper arm switch SWH may be set to be lower than the threshold voltage Vth of the upper arm switch SWH so as to lower the possibility of occurrence of a short-circuit between upper and lower arms. Note that the determination voltage of the lower arm switch SWL may be set to be higher than the threshold voltage Vth of the lower arm switch SWL similar to the determination voltage of the upper arm switch SWH or may be set to be lower than the threshold voltage Vth of the lower arm switch SWL.

For the upper arm driving unit 70, it is not limited to a determination whether the upper arm switch SWH turns ON or OFF based on the gate voltage VgH of the upper arm switch SWH. For example, in the case where the upper arm driving unit 70 acquires the drain current IdH of the upper arm switch SWH and determines that the acquired drain current IdH is higher than or equal to a predetermined threshold, the upper arm driving unit 70 may determine that the upper arm switch SWH turns ON, and may determine that the upper arm switch SWH turns OFF in the case where the acquired drain current IdH is less than a predetermined threshold. Further, the upper arm driving unit 70 may determine whether the upper arm switch SWH turns ON or OFF based on the drain voltage of the upper switch SWH instead of the drain current IdH of the upper arm switch SWH.

The lower arm driving unit 80 may perform, similar to the upper arm driving unit 70, a determination whether the lower arm switch SWL is ON or OFF based on the drain current IdL or the drain voltage of the lower arm switch SWL.

Further, for example, the upper arm driving unit 70 may count a time from when the logic state of the upper arm switching command INH is changed to be L, thereby determining whether the state of the upper arm switch SWH is ON or OFF. In this case, the upper arm driving unit 70 determines that the upper arm switch SWH is ON when an elapsed time from when the logic state of the upper arm switching command INH is changed to be L is less than a predetermined time, and determines that the upper arm switch SWH turns OFF when the elapsed time reaches the predetermined time. The lower arm driving unit 80 may perform, similar to the upper arm driving unit 70, a determination whether the lower arm switch SWL is ON or OFF based on an elapsed time from when the logic state of the lower arm switching command INL is changed to be L.

It is not limited to a configuration in which the drain of the upper arm OFF-hold switch is directly connected to the gate of the upper arm switch SWH and the source of the upper arm OFF-hold switch 76 is connected to the source of the upper arm switch SWH. A configuration may be employed in which a resistor having smaller resistance than that of the upper arm discharge resistor 74 is connected to at least one of the drain or the source of the upper arm OFF-hold switch 76. In this case, the upper arm OFF-hold switch 76 is turned ON, whereby gate charges of the upper arm switch SWH are discharged via the resistor connected to the upper arm OFF-hold switch 76 and the upper arm OFF-hold switch 76. Further, the lower arm OFF-hold switch 86 may be connected to a resistor having a smaller resistance than that of the lower arm discharge resistor 84 similar to the upper arm OFF-hold switch 76.

As a modification for the discharge rate, it is not limited to the resistance of the discharge resistor. For example, the upper arm driving unit 70 may change a potential at a portion to which gate charges are discharged (discharge portion), thereby changing the discharge rate. Specifically, the discharge portion may be a negative voltage source. The output voltage of the negative voltage source may be set to be lower than the source voltage of the upper arm switch SWH. In this case, the discharge rate can be set such that the lower the output voltage of the negative voltage source, the higher the discharge rate is. Further, similar to the upper arm driving unit 70, the lower arm driving unit 80 may change a potential at a portion connected to the source of the lower arm discharge switch 85, to which gate charges are discharged, thereby changing the discharge rate.

Further, for example, the upper arm driving unit 70 may change the gate voltage of the upper arm discharge switch 75, thereby changing the discharge rate. In this case, since the higher the gate voltage of the upper arm discharge switch 75, the lower the ON-resistance of the upper arm discharge switch 75 is, the discharge rate can be set to be higher. Note that, similar to the upper arm driving unit 70, the lower arm driving unit 80 may change the gate voltage of the discharge switch 85, thereby changing the discharge rate.

The microprocessor 50 may control the OFF side switch and the ON side switch, instead of a control that changes the logic state of the switching command of the OFF side switch to be L and simultaneously changes the logic state of the switching command of the ON side switch to be H, such that the switching command of the OFF side switch is changed to be L, thereafter the switching command of the ON side switch is changed to be H. In this case, the respective switching commands INH and INL may be set such that the dead time target value DT* is shorter than the turn-off period toff of the OFF side switch. Note that the respective switching commands INH and INL may be set such that the dead time target value DT* is longer than the turn-off period toff instead of the setting where the dead time target value DT* is shorter than the turn-off period toff.

Moreover, the microprocessor 50 may change the switching command of the ON side switch to be H prior to a changing for the switching command of the OFF side switch to be L.

According to the first embodiment, a control when determined that the gate voltage VgH of the upper arm switch SWH is less than the determination voltage of the upper arm switch SWH may be changed. Specifically, the upper arm switch 75 may be turned OFF when the logic state of the upper arm transmission signal SgH is changed to be H.

Moreover, a control in the case where it is determined that the gate voltage VgL of the lower arm switch SWL is less than the determination voltage of the lower arm switch SWL may be changed. Specifically, the lower arm discharge switch 85 may be controlled to be OFF when the logic state of the lower arm transmission signal SgL is changed to be H.

As a semiconductor switch that constitutes the inverter 15, it is not limited to N-channel MOSFET, but may be IGBT, for example. In this case, the high voltage side terminal serves as a collector and the low voltage side terminal serves as an emitter. Further, a free-wheel diode may be reversely connected in parallel to each switch.

The moving body to which the control system is mounted is not limited to vehicles, but may be aircrafts or ship. Moreover, object to which the control system is mounted is not limited to moving body.

The present disclosure has been described in accordance with the embodiments. However, the present disclosure is not limited to the embodiments and structure thereof. The present disclosure includes various modification examples and modifications within the equivalent configurations. Further, various combinations and modes and other combinations and modes including one element or more or less elements of those various combinations are within the range and technical scope of the present disclosure.

Hereinafter, significant configurations obtained from the above-described embodiments will be described.

### (Configuration 1)

A switch driving apparatus (40) that drives upper and lower arm switches (SWH, SWL) mutually connected in series, the switch driving apparatus comprising:
a discharge unit (70, 74, 75, 80, 84, 85) that causes electric charges to be discharged from a gate of an OFF side switch as an one switch in the upper and lower arm switches, thereby turning the OFF side switch to be OFF;
a determination unit that determines whether the OFF side switch is ON or OFF;
a fast-discharge unit (70, 76, 80, 86) that changes, when the determination unit determines that the OFF side switch is turned OFF, a discharge rate of discharging in which electric charges in the gate of the OFF side switch is discharged, to be higher than a discharge rate in a period from when electric charges in the gate of the OFF side switch start to discharge to when determined that the OFF side switch is turned OFF; and
a charge unit (70, 72, 73, 80, 82, 83) that charges, when the determination unit determines that the OFF side switch is turned OFF, a gate of an ON side switch in an arm opposite to an arm of the OFF side switch in the upper and lower arm switches with electric charges, thereby turning the ON side switch to be ON.

### (Configuration 2)

The switch driving apparatus according to configuration 1,

wherein
the switch driving apparatus is provided with an acquiring unit (70, 80) that acquires a gate voltage of the OFF side switch; and
the determination unit determines that the OFF side switch is turned ON when the acquired gate voltage is higher than or equal to a threshold voltage of the OFF side switch, and determines that the ON side switch is turned OFF when the gate voltage is less than the threshold voltage.

### (Configuration 3)

The switch driving apparatus according to configuration 1 or 2,

wherein
the fast-discharge unit includes an OFF-hold switch (76, 86) that cutoff between a gate of the OFF side switch and a low voltage side terminal of the OFF side switch when the OFF-hold switch is turned OFF, and short-circuits between the gate of the OFF side switch and the low voltage side terminal of the OFF side switch when the OFF-hold switch is turned ON; and
the OFF-hold switch is turned ON when determined that the OFF side switch is turned OFF, thereby changing the discharge rate to be higher than the discharge rate in a period from when electric charges in the gate of the OFF side switch start to discharge to when determined that the OFF side switch it turned OFF.

### (Configuration 4)

The switch driving apparatus according to any one of configurations 1 to 3,

wherein
the determination unit is provided in a high voltage region;
the discharge unit includes an upper arm discharge unit (70, 74, 75) and a lower arm discharge unit in the high voltage region, the upper arm discharge unit discharging electric charges from a gate of the upper arm switch and the lower arm discharge unit discharging electric charges from a gate of the lower arm switch;
the charge unit includes an upper arm charge unit (70, 72, 73) and a lower arm charge unit (80, 82, 83) in the high voltage region, the upper arm charge unit charging electric charges to a gate of the upper arm switch and the lower arm charge unit charging electric charges to a gate of the lower arm switch;
a first transmission unit (41) is provided in the high voltage region, the first transmission unit transmitting a signal indicating a determination that the upper arm switch is turned ON or OFF which is determined by the determination unit, to the lower arm discharge unit and the lower arm charge unit;
a second transmission unit (42) is provided in the high voltage region, the second transmission unit transmitting a signal indicating a determination that the lower arm switch is turned ON or OFF which is determined by the determination unit, to the upper arm discharge unit and the upper arm charge unit;
a command generation unit (50) is provided in a low voltage region electrically isolated from the high voltage region, the command generation unit generating a switching command that commands a switching state of the upper and lower arm switches and transmitting the switching command to the upper arm discharge unit, the lower arm discharge unit, the upper arm charge unit and the lower arm charge unit;
the upper arm discharge unit discharges, when receiving the switching command for changing the upper arm switch to be OFF, electric charges from a gate of the upper arm switch as the OFF side switch;
the lower arm discharge unit discharges, when receiving the switching command for changing the lower arm switch to be OFF, electric charges from a gate of the lower arm switch as the OFF side switch;
the upper arm charge unit charges, when receiving the switching command for changing the upper arm switch to be ON and receiving a signal indicating a determination that the lower arm switch is turned OFF from the second transmission unit, electric charges to a gate of the upper arm switch as the ON side switch; and
the lower arm charge unit charges, when receiving the switching command for changing the lower arm switch to be ON and receiving a signal indicating a determination that the upper arm switch is turned OFF from the first transmission unit, electric charges to a gate of the lower arm switch as the ON side switch.

### (Configuration 5)

The switch driving apparatus according to configuration 4,

wherein
the command generation unit sets a target value of a dead time as a period set by the switching command where both of the upper arm switch and the lower switch are caused to be OFF, to be shorter than a period from when an OFF command of the OFF side switch is transmitted to when a gate voltage of the OFF side switch becomes lower than a threshold voltage of the OFF side switch.

### CONCLUSION

The present disclosure provides a switch driving apparatus capable of reducing a dead time while suppressing occurrence of a short-circuit between an upper arm unit and a lower arm unit.

According to the present disclosure, a switch driving apparatus that drives upper and lower arm switches mutually connected in series is provided. The switch driving apparatus includes: a discharge unit that causes electric charges to be discharged from a gate of an OFF side switch as an one switch in the upper and lower arm switches, thereby turning the OFF side switch to be OFF; a determination unit that determines whether the OFF side switch is ON or OFF; a fast-discharge unit that changes, when the determination unit determines that the OFF side switch is turned OFF, a discharge rate of discharging in which electric charges in the gate of the OFF side switch is discharged, to be higher than a discharge rate in a period from when electric charges in the gate of the OFF side switch start to discharge to when determined that the OFF side switch is turned OFF; a charge unit that charges, when the determination unit determines that the OFF side switch is turned OFF, a gate of an ON side switch in an arm opposite to an arm of the OFF side switch in the upper and lower arm switches with electric charges, thereby turning the ON side switch to be ON.

According to the present disclosure, when determined that the OFF side switch is turned OFF, the discharge rate is set to be higher than a discharge rate in a period from when electric charges in the gate of the OFF side switch start to discharge to when determined that the OFF side switch is turned OFF. Thus, after determining that the OFF side switch is turned OFF, the gate voltage of the OFF side switch rapidly decreases. As a result, after determining that the OFF side switch is turned OFF, a current flowing through the OFF side switch is promptly cutoff.

Also, when determined that the OFF side switch is turned OFF, the gate of the ON side switch is charged with electric charges. In other words, since the ON side switch is turned ON after determining that the OFF side switch in an opposite arm is turned OFF, a short-circuit between the upper and lower units can be avoided.

Since the drain current of the OFF side switch is cutoff and the gate of the ON side switch is charged with electric charges in response to a determination that the OFF side switch is turned OFF as a trigger, the dead time can be shortened while suppressing occurrence of a short-circuit between upper and lower arm units.

What is claimed is:

1. A switch driving apparatus that drives upper and lower arm switches mutually connected in series, the switch driving apparatus comprising:
a discharge unit that causes electric charges to be discharged from a gate of an OFF side switch as an one switch in the upper and lower arm switches, thereby turning the OFF side switch to be OFF;
a determination unit that determines whether the OFF side switch is ON or OFF;
a fast-discharge unit that changes, when the determination unit determines that the OFF side switch is turned OFF, a discharge rate of discharging in which electric charges in the gate of the OFF side switch is discharged, to be higher than a discharge rate in a period from when electric charges in the gate of the OFF side switch start to discharge to when determined that the OFF side switch is turned OFF; and
a charge unit that charges, when the determination unit determines that the OFF side switch is turned OFF, a gate of an ON side switch in an arm opposite to an arm of the OFF side switch in the upper and lower arm switches with electric charges, thereby turning the ON side switch to be ON.

2. The switching apparatus according to claim 1,
wherein
the discharge unit starts to discharge electric charges from the gate of the OFF side switch when determined that a switching command of the OFF side switch is changed to be an OFF command;
the charge unit does not charge electric charges to the gate of the ON side switch when the determination unit determines that the OFF side switch is in an ON state even when determined that a switching command of the ON side switch is an ON command;
the charge unit starts to charge electric charges to the gate of the ON side switch when determined that the switching command of the ON side switch is an ON command and the determination unit determines that the OFF side switch turns OFF.

3. The switch driving apparatus according to claim 2,
wherein
the switch driving apparatus is provided with an acquiring unit that acquires a gate voltage of the OFF side switch; and
the determination unit determines that the OFF side switch is in an ON state when the acquired gate voltage is higher than or equal to a threshold voltage of the OFF side switch, and determines that the OFF side switch is turned OFF when the acquired gate voltage is less than the threshold voltage.

4. The switch driving apparatus according to claim 2,
wherein
the fast-discharge unit includes an OFF-hold switch that cutoff between a gate of the OFF side switch and a low voltage side terminal of the OFF side switch when the OFF-hold switch is turned OFF, and short-circuits between the gate of the OFF side switch and the low voltage side terminal of the OFF side switch when the OFF-hold switch is turned ON; and
the OFF-hold switch is turned ON when determined that the OFF side switch is turned OFF, thereby changing the discharge rate to be higher than the discharge rate in a period from when electric charges in the gate of the OFF side switch start to discharge to when determined that the OFF side switch it turned OFF.

5. The switch driving apparatus according to claim 2,
wherein
the determination unit is provided in a high voltage region;
the discharge unit includes an upper arm discharge unit and a lower arm discharge unit in the high voltage region, the upper arm discharge unit discharging electric charges from a gate of the upper arm switch and the lower arm discharge unit discharging electric charges from a gate of the lower arm switch;
the charge unit includes an upper arm charge unit and a lower arm charge unit in the high voltage region, the upper arm charge unit charging electric charges to a gate of the upper arm switch and the lower arm charge unit charging electric charges to a gate of the lower arm switch;
a first transmission unit is provided in the high voltage region, the first transmission unit transmitting a signal indicating a determination that the upper arm switch is turned ON or OFF which is determined by the determination unit, to the lower arm discharge unit and the lower arm charge unit;
a second transmission unit is provided in the high voltage region, the second transmission unit transmitting a signal indicating a determination that the lower arm switch is turned ON or OFF which is determined by the determination unit, to the upper arm discharge unit and the upper arm charge unit;
a command generation unit is provided in a low voltage region electrically isolated from the high voltage region, the command generation unit generating a switching command of the upper and lower arm switches and transmitting the switching command to the upper arm discharge unit, the lower arm discharge unit, the upper arm charge unit and the lower arm charge unit;
the upper arm discharge unit discharges, when receiving an OFF command as the switching command of the upper arm switch, electric charges from a gate of the upper arm switch as the OFF side switch;
the lower arm discharge unit discharges, when receiving an OFF command as the switching command of the lower arm switch, electric charges from a gate of the lower arm switch as the OFF side switch;
the upper arm charge unit charges, when receiving an ON command as the switching command of the upper arm switch and receiving a signal indicating a determination that the lower arm switch is turned OFF from the second transmission unit, electric charges to a gate of the upper arm switch as the ON side switch; and
the lower arm charge unit charges, when receiving an ON command as the switching command of the lower arm switch and receiving a signal indicating a determination that the upper arm switch is turned OFF from the first transmission unit, electric charges to a gate of the lower arm switch as the ON side switch.

6. The switch driving apparatus according to claim 5,
wherein
the command generation unit sets a target value of a dead time as a period set by the switching command where both of the upper arm switch and the lower switch are caused to be OFF, to be shorter than a period from when an OFF command of the OFF side switch is transmitted to when a gate voltage of the OFF side switch becomes lower than a threshold voltage of the OFF side switch.
